(19) United States
(12) Patent Application Publication
(10) Pub. No.: US 2015/0061008 A1
(43) Pub. Date: Mar. 5, 2015

(54) LDMOSFET HAVING A BRIDGE REGION FORMED BETWEEN TWO GATE ELECTRODES

(71) Applicant: Maxim Integrated Products, Inc., San Jose, CA (US)

(72) Inventors: Joel M. McGregor, Nelson (CA); Frederick P. Giles, San Jose, CA (US)

(21) Appl. No.: 14/534,540

(22) Filed: Nov. 6, 2014

Related U.S. Application Data
(63) Continuation of application No. 13/035,664, filed on Feb. 25, 2011.
Application No. 13/035,664 is a continuation-in-part of application No. 12/618,546, filed on Nov. 13, 2009.
Application No. 12/618,546 is a continuation-in-part of application No. 12/618,576, filed on Nov. 13, 2009.

(51) Int. Cl. H01L 27/088; H01L 29/06; H01L 29/78; H01L 29/10; H01L 29/16; H01L 29/49

(52) U.S. Cl. CPC H01L 27/0883; H01L 29/16; H01L 29/4916; H01L 29/7816; H01L 29/1095; H01L 29/0653
USPC 257/337

(57) ABSTRACT

A split gate power transistor includes a laterally configured power MOSFET including a doped silicon substrate, a stepped gate oxide layer formed on a surface of the substrate, and a split polysilicon layer formed over the stepped gate oxide layer. The stepped gate oxide layer includes a first gate oxide layer having a first thickness and a second gate oxide layer having a second thickness that is greater than the first thickness. The polysilicon layer is cut into two electrically isolated portions, a first portion forming a switching gate positioned over the first gate oxide layer and a first portion of a channel region of the substrate, and a second portion forming a static gate formed over the second gate oxide layer and a second portion of the channel region. A switching voltage is applied to the switching gate and a constant voltage is applied to the static gate.

### RELATED APPLICATIONS

This patent application is a continuation of U.S. patent application Ser. No. 13/035,664, filed Feb. 25, 2011, and entitled, “LDMOSFET HAVING A BRIDGE REGION FORMED BETWEEN TWO GATE ELECTRODES.” U.S. patent application Ser. No. 13/035,664 is a continuation in part of U.S. patent application Ser. No. 12/618,546, filed Nov. 13, 2009, and entitled, “CMOS COMPATIBLE LOW GATE CHARGE LATERAL MOSFET.” U.S. patent application Ser. No. 13/035,664 is also a continuation in part of U.S. patent application Ser. No. 12/618,576, filed Nov. 13, 2009, and entitled, “CMOS COMPATIBLE LOW GATE CHARGE HIGH VOLTAGE PMOS.” This application incorporates U.S. patent application Ser. No. 12/618,546, U.S. patent application Ser. No. 12/618,576, and U.S. patent application Ser. No. 13/035,664 in their entireties by reference.

### FIELD OF THE INVENTION

The present invention relates to the field of power transistors. More particularly, the present invention relates to the field of integrated MOS power transistors with reduced gate charge.

### BACKGROUND

A power supply is a device or system that supplies electrical or other types of energy to an output load or group of loads. The term power supply can refer to a main power distribution system and other primary or secondary sources of energy. A switched-mode power supply, switching-mode power supply or SMPS, is a power supply that incorporates a switching regulator. While a linear regulator uses a transistor biased in its active region to specify an output voltage, a SMPS actively switches a transistor between full saturation and full cutoff at a high rate. The resulting rectangular waveform is then passed through a low-pass filter, typically an inductor and capacitor (LC) circuit, to achieve an approximated output voltage.

SMPS is currently the dominant form of voltage conversion device because of its high power conversion efficiency, small size and weight, and low cost. SMPS takes input power from a source, such as a battery or wall socket, and converts the input power into short pulses according to the demand for power from the circuits coupled to the SMPS output.

MOSFETs (Metal-Oxide-Semiconductor Field-Effect Transistors) are commonly used in SMPS. MOSFETs are commonly manufactured separately, as discrete transistors. Each MOSFET is then connected to other integrated circuits that are part of the SMPS. Using discrete devices in this manner increases cost and size of the overall SMPS.

High performing MOSFETs are significant to the conversion efficiency of SMPS because MOSFETs are some of the most power dissipating components in the SMPS. Also, the maximum possible switching frequency of the MOSFETs dictates the size, cost, and power losses in the inductors and capacitors included in the SMPS output filter circuits. Under normal SMPS operation, MOSFETS are turned on and off rapidly, so for efficient operation the MOSFETs should have low values of both resistance and gate capacitance.

A MOSFET has a gate, a drain, and a source terminal, as well as a fourth terminal called the body, base, bulk, or substrate. The substrate simply refers to the bulk of the semiconductor in which the gate, source, and drain lie. The fourth terminal functions to bias the transistor into operation. The gate terminal regulates electron flow through a channel region in the substrate, either enabling or blocking electron flow through the channel. Electrons flow through the channel from the source terminal towards the drain terminal when influenced by an applied voltage.

The channel of a MOSFET is doped to produce either an N-type semiconductor or a P-type semiconductor. The drain and source may be doped of opposite type to the channel, in the case of enhancement mode MOSFETs, or doped of similar type to the channel as in depletion mode MOSFETs. The MOSFET utilizes an insulator, such as silicon dioxide, between the gate and the substrate. This insulator is commonly referred to as the gate oxide. As such, the gate terminal is separated from the channel in the substrate by the gate oxide.

When a voltage is applied between the gate and source terminals, the electric field generated penetrates through the gate oxide and creates a so-called “inversion layer”, or channel, at the semiconductor-insulator interface. The inversion channel is of the same type, P-type or N-type, as the source and drain, so as to provide a channel through which current can pass. Varying the voltage between the gate and substrate modulates the conductivity of this layer, which functions to control the current flow between drain and source.

A power MOSFET is a specific type of MOSFET widely used as a voltage switch, for example less than 200V. A lateral power MOSFET refers to a configuration where both the drain and the source are positioned laterally of each other, such as both at the top surface of the substrate. This is in contrast to a vertical power MOSFET where the drain and source are stacked vertically relative to each other, such as the source at the top surface of the substrate and the drain at the bottom surface.

One limiting factor in how fast the power MOSFET can be switched on and off is the amount of gate charge needed to turn the transistor on and off The gate charge refers to the number of electrons that are moved into and out of the gate to turn the transistor on and off, respectively. The larger the needed gate charge, the more time to switch the transistor on and off. There is an advantage to quickly switching the power transistor in a switch-mode power supply. The higher the frequency, the smaller the size of the discrete components used in the gate drive circuit of the SMPS. Smaller components are less expensive than larger components.

FIG. 1 illustrates a cut-out side view of an example configuration of a conventional lateral power MOSFET configured for lower voltage applications, such as 5V or lower. In this example configuration, a substrate 60 is doped to form a P-type region 62, a P+ region 70, an N+ region 72 and a N+ region 68. The power transistor 52 includes a double diffused source 66 having a merged contact 74 between the P+ region 70 and the N+ region 72. The contact 74 shorts the P+ region 70 and the N+ region 72 together. The contact 74 functions as a source contact of the power transistor, and the source is shorted to the body of the substrate, which is P-type in this example configuration. A source contact terminal 92 is coupled to the contact 74, and therefore to the source 66. The N+ region 68 functions as the drain of the power transistor. A drain contact terminal 90 is coupled to the drain 68.

A gate oxide 78 is formed on the top surface of the substrate 60. A polysilicon gate 80 is formed over the gate oxide 78. As shown in FIG. 1, the gate oxide layer 78 between the polysilicon gate 80 and the substrate 60 is a thin oxide layer having the same thickness along its entire length. One end of the polysilicon gate 80 extends over the N+ region 72 and the other end of the polysilicon gate 80 extends over the N+ region 68. In an example application, the MOSFET is an enhancement-mode 5V N-channel MOSFET. In order to support 5V on the gate and the drain, the thickness of the gate oxide is approximately 14 nm, and length of the gate is approximately 0.6 um, where the length refers to the horizontal direction in FIG. 1.

When voltage is applied to the polysilicon gate 30, a channel region is formed underneath the polysilicon gate 80 and in the P-type region 62 of the substrate 60. In other words, the channel region is formed where the polysilicon gate 80 overlaps the P-type region 62. One of the sources of inefficiency in a switch-mode power supply is the power required to charge and discharge the gate electrode, such as the polysilicon gate 80, of the power transistor every cycle.

FIG. 2 illustrates a cut-out side view of an example configuration of a conventional lateral power MOSFET configured for higher voltage applications, such as 10V-40V or higher, than those performed by the power transistor in FIG. 1. The power MOSFET 2 is configured as a DMOSFET (double diffused MOSFET) having a double diffused N-type drain well. In the example configuration of FIG. 2, a substrate 10 is doped to form a P-type region, or well, 12 and a N-type region, or well, 14. The P-type well 12 includes a double diffused source 16 having a merged contact 24 between a P+ region 20 and a N+ region 22. The contact 24 shorts the P+ region 20 and the N+ region 22 together. The contact 24 functions as a source contact of the power transistor, and the source is shorted to the body of the substrate, which is P-type in this example configuration. A source contact terminal 42 is coupled to the contact 24, and therefore to the source 16. The substrate 10 is also doped to form a N+ region 18 within the N-type region 14. The N+ region 18 functions as the drain of the power transistor. A drain contact terminal 40 is coupled to the drain 18. A trench 26 is formed in a top surface of the substrate 10. The trench 26 is filled with field oxide. The trench 26 can be formed using Shallow Trench Isolation (STI) and in this case the field oxide filled trench is referred to as a shallow trench isolation (STI) region. The STI region is formed to enable higher voltage applications.

A gate oxide 28 is formed on the top surface of the substrate 10. A polysilicon gate 30 is formed over the gate oxide 28. As shown in FIG. 1, the gate oxide layer 28 between the polysilicon gate 30 and the substrate 10 is a thin oxide layer having the same thickness along its entire length. The polysilicon gate 30 extends over the STI region to support high drain-to-gate voltage.

There are three main regions in the substrate 10 relative to the operation of the power transistor 2: a channel region, a transition region, and a drift region. The channel region is formed underneath the polysilicon gate 30 and in the P-type region 12 of the substrate 10. In other words, the channel region is formed where the polysilicon gate 30 overlaps the P-type region 12. The drift region is the portion of the N-type region 12 underneath the trench 26, or the STI region. The drift region is where most of the drain-to-gate voltage is dropped in the transistor off state. The STI region is necessary to achieve a high drain-to-gate voltage. If the polysilicon gate 30 were to instead terminate over the thin gate oxide, this would result in too high a voltage across the gate oxide and the power transistor would not function. As such, the STI region and the polysilicon gate extension over the STI region are necessary to drop the high gate-to-drain voltage.

The transition region is the portion of the N-type region 14 underneath the gate oxide 28 and the polysilicon gate 30. The transition region provides a current flow path from the channel region to the drift region when the power transistor is turned on. The transition region is also referred to as the accumulation region or the neck region. In many applications, the transition region accounts for the largest single component of on-resistance in the power MOSFET. The length of the transition region is an important design consideration, where the length refers to the horizontal direction in FIG. 1. If the length is too short, the on-resistance of the power MOSFET increases, and the device suffers from early quasi-saturation when turned on hard. If the length is too long, the on-resistance saturates, the specific on-resistance increases, and the breakdown voltage drops. The portion of the polysilicon gate 30 positioned over the transition region accounts for a significant portion of the gate capacitance, and therefore the gate charge.

### SUMMARY

A split gate power transistor includes a laterally configured power MOSFET having a doped silicon substrate, a stepped gate oxide layer formed on a surface of the substrate, and a split polysilicon layer formed over the stepped gate oxide layer. The stepped gate oxide layer includes a first portion having a first thickness and a second portion having a second thickness, where the first thickness is less than the second thickness. The polysilicon layer is cut into two electrically isolated portions, a first portion forming a polysilicon switching gate positioned over the first portion of the gate oxide layer, and a second portion forming a polysilicon static gate positioned over the second portion of the gate oxide layer. The polysilicon switching gate and the first portion of the gate oxide layer are positioned over a first channel region of the substrate. The polysilicon static gate and the second portion of the gate oxide layer are positioned over a second channel region of the substrate. The first channel region and the second channel region are bridged by a doped bridge region in the substrate. The switching gate is electrically coupled to a first voltage source and the static gate is electrically coupled to a second voltage source. The rated gate-to-source voltage of the polysilicon switching gate is lower than the rated gate-tosource voltage of the polysilicon static gate since the thickness of the gate oxide layer underneath the polysilicon switching gate is less than the thickness of the gate oxide layer underneath the polysilicon static gate. In some embodiments, the polysilicon switching gate is configured as an enhancement-mode MOSFET and the polysilicon static gate is configured as a depletion-mode MOSFET. In other embodiments, the polysilicon switching gate and the polysilicon static gate are both configured as enhancement-mode MOSFETs.

In an aspect, a split gate power transistor is disclosed. The split gate power transistor includes: a doped substrate comprising a source, a first channel region, a bridge, a second channel region, and a drain, wherein the first channel region is positioned between the source and the bridge, and the second channel region is positioned between the bridge and the drain; a first gate oxide layer positioned on the substrate over at least the first channel region; a second gate oxide layer positioned on the substrate over at least the second channel region, wherein a thickness of the first gate oxide layer is less than a thickness of the second gate oxide layer; a first gate positioned on the first gate oxide layer and over the first channel region; and a second gate positioned on the second gate oxide layer and over the second channel region, wherein the first gate is separated from the second gate such that at least a portion of the bridge is uncovered by both the first gate and the second gate.

The first gate is electrically coupled to a first voltage supply, and the second gate is electrically coupled to a second voltage supply. The first gate and the second gate are electrically isolated from each other. In some embodiments, a constant voltage is applied to the second gate and a switching voltage is applied to the first gate. The constant voltage is a bias voltage level that is less than a breakdown voltage of the first gate oxide. In some embodiments, the source, the first gate, and the bridge form an enhancement-mode transistor and the bridge, the second gate, and the drain form a depletion-mode transistor. The enhancement-mode transistor can be an enhancement-mode 2V MOSFET and depletion-mode transistor can be a depletion-mode 5V MOSFET. In other embodiments, the source, the first gate, and the bridge form a first enhancement-mode transistor and the bridge, the second gate, and the drain form a second enhancement-mode transistor. In some embodiments, the first gate and the second gate comprise polysilicon. In some embodiments, the source and the bridge are N-type regions and the first channel and the second channel are P-type regions. In other embodiments, the source, the second channel, and the bridge are N-type regions and the first channel is a P-type region. In some embodiments, the substrate comprises a silicon substrate. In some embodiments, the source comprises a double-diffused region.

In another aspect, a split gate power transistor is disclosed. The split gate power transistor includes: a doped substrate comprising a source, a bridge, a first channel region, and a second channel region within a first doped region, a drain and a transition region within a second doped region, and a trench within a second doped region, wherein the trench is formed in a first surface of the substrate and the trench is filled with field oxide, further wherein the first channel region is positioned between the source and the bridge, the second channel region is positioned between the bridge and the transition region, the transition region is positioned between the second channel region and the trench, and the trench is positioned between the transition region and the drain; a first gate oxide layer positioned on the first surface of the substrate over at least the first channel region; a second gate oxide layer positioned on the first surface of the substrate over at least the second channel region, wherein a thickness of the first gate oxide layer is less than a thickness of the second gate oxide layer; a first gate positioned on the first gate oxide layer and over the first channel region; and a second gate positioned on the second gate oxide layer and over the second channel region, the transition region, and a portion of the trench, wherein the first gate is separated from the second gate such that at least a portion of the bridge is uncovered by both the first gate and the second gate.

In yet another aspect, a method of fabricating a power transistor is disclosed. The method includes: doping a substrate to form a source and a drain, wherein a channel region is positioned between the source and the transition region; applying a stepped gate oxide to a top surface of the substrate, wherein the stepped gate oxide comprises a first gate oxide layer having a first thickness and a second gate oxide layer having a second thickness, the first thickness is less than the second thickness; forming a conductive layer over the channel region; removing the conductive layer and the stepped gate oxide over a first portion of the channel region, thereby forming two separate conductive layer portions including a first conductive layer portion positioned over the first gate oxide layer and a second portion of the channel region, and a second conductive layer portion positioned over the second gate oxide layer and a third portion of the channel region; and doping the first conductive layer portion, the second conductive layer portion, and the first portion of the channel region exposed where the conductive layer and the stepped oxide are removed, thereby forming a doped bridge region between the first portion of the channel region and the second portion of the channel region.

### BRIEF DESCRIPTION OF THE DRAWINGS

FIG. 1 illustrates a cut-out side view of an example configuration of a conventional lateral power MOSFET configured for lower voltage applications.

FIG. 2 illustrates a cut-out side view of an example configuration of a conventional lateral power MOSFET configured for higher voltage applications than those performed by the power MOSFET in FIG. 1.

FIG. 3 illustrates a cut-out side view of a split gate laterally-configured power transistor according to another embodiment of the present disclosure.

FIG. 4 illustrates a gate charge curve for a power MOSFET, such as that shown in FIG. 1, and the first embodiment of the split gate power MOSFET, such as that of FIG. 3.

FIG. 5 illustrates a cut-out side view of a split gate laterally-configured power transistor according to another embodiment of the present disclosure.

FIG. 6 illustrates a cut-out side view of a split gate laterally-configured power transistor according to another embodiment of the present disclosure.

FIG. 7 illustrates a gate charge curve for a power MOSFET, such as that shown in FIG. 2, and the split gate power MOSFET, such as that of FIG. 5.

FIG. 8 illustrates a cut-out side view of a split gate laterally-configured power transistor according to another embodiment of the present disclosure of the present disclosure.

Embodiments of the split gate power transistor are described relative to the several views of the drawings. Where appropriate and only where identical elements are disclosed and shown in more than one drawing, the same reference numeral will be used to represent such identical elements.

### DETAILED DESCRIPTION

Embodiments of the present application are directed to a split gate power transistor. Those of ordinary skill in the art will realize that the following detailed description of the split gate power transistor is illustrative only and is not intended to be in any way limiting. Other embodiments of the split gate power transistor will readily suggest themselves to such skilled persons having the benefit of this disclosure.

Reference will now be made in detail to implementations of the split gate power transistor as illustrated in the accompanying drawings. The same reference indicators will be used throughout the drawings and the following detailed description to refer to the same or like parts. In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Embodiments of a split gate power transistor include a laterally configured power MOSFET having a doped silicon substrate, a stepped gate oxide layer formed on a surface of the substrate, and a split polysilicon layer formed over the gate oxide layer. The stepped gate oxide layer includes a first portion having a first thickness and a second portion having a second thickness, where the first thickness is less than the second thickness. The polysilicon layer is cut into two electrically isolated portions, a first portion forming a polysilicon switching gate positioned over the first portion of the gate oxide layer, and a second portion forming a polysilicon static gate positioned over the second portion of the gate oxide layer. The polysilicon switching gate and the first portion of the gate oxide layer are positioned over a first channel region of the substrate. The polysilicon static gate and the second portion of the gate oxide layer are positioned over a second channel region of the substrate. The first channel region and the second channel region are bridged by a doped bridge region in the substrate. The bridge is doped the same type as the source and the drain. The switching gate is electrically coupled to a first voltage source and the static gate is electrically coupled to a second voltage source. In an example application, a constant voltage is applied to the static gate, and a high frequency switching voltage is applied to the switching gate.

The polysilicon layer is cut over a channel region, or body, of the substrate. The bridge is formed during fabrication of the switching gate and the static gate. When the polysilicon layer is cut, a portion of the substrate is exposed where the cut portion of the polysilicon is removed. The two polysilicon portions and the exposed portion of substrate are doped. During this doping process, the doped bridge region is formed at the exposed portion of the substrate. The bridge splits the would be channel region into the first channel region and the second channel region. The first channel region is positioned between the source and the bridge. The second channel region is positioned between the bridge and the drain.

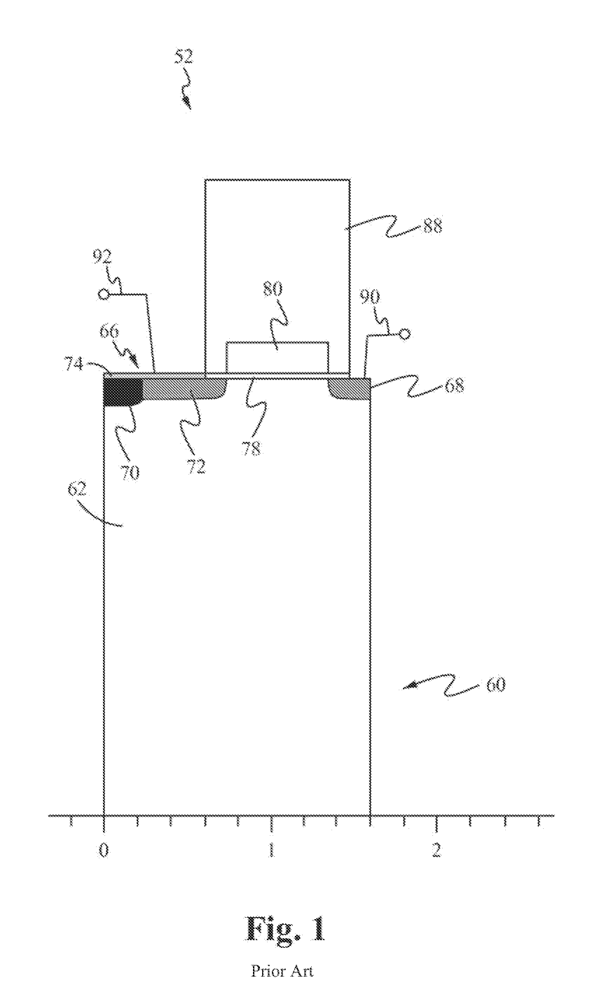

In conventional power MOSFETs, such as that shown in FIG. 1, applying a switching voltage to the gate amplifies the gate-to-drain capacitance due to the Miller effect. In the split gate power transistor, the switching portion of the gate, the switching gate, regulates a smaller channel region and requires a smaller gate voltage for turn on than the conventional power MOSFET. The remaining portion of the channel region is regulated by constant gate voltage supplied to the static gate. This reduces, if not eliminates, the Miller capacitance between the gate and the drain. Also, by reducing the area of the switching gate, the amount of charge, the gate charge, transferred during each switching cycle is reduced. As used herein, the gate charge is the amount of charge needed to switch the device from OV to fully turned on. The gate charge determines how fast a switch is turned on and off Reducing the gate charge allows for higher-frequency switching operation. The higher frequency allows for the use of smaller discrete components which reduces costs.

The split gate power transistor configuration is applicable to all switchable power supply integrated circuits that have internal switches. The fabrication process for the split gate power transistor is CMOS compatible. As such, the split gate power transistor can be manufactured monolithically with the output circuit of the SMPS circuit. This configuration is not limited to integrated MOSFETs. The split gate power transistor configuration can be applied to any lateral power MOSFET, either integrated or discrete.

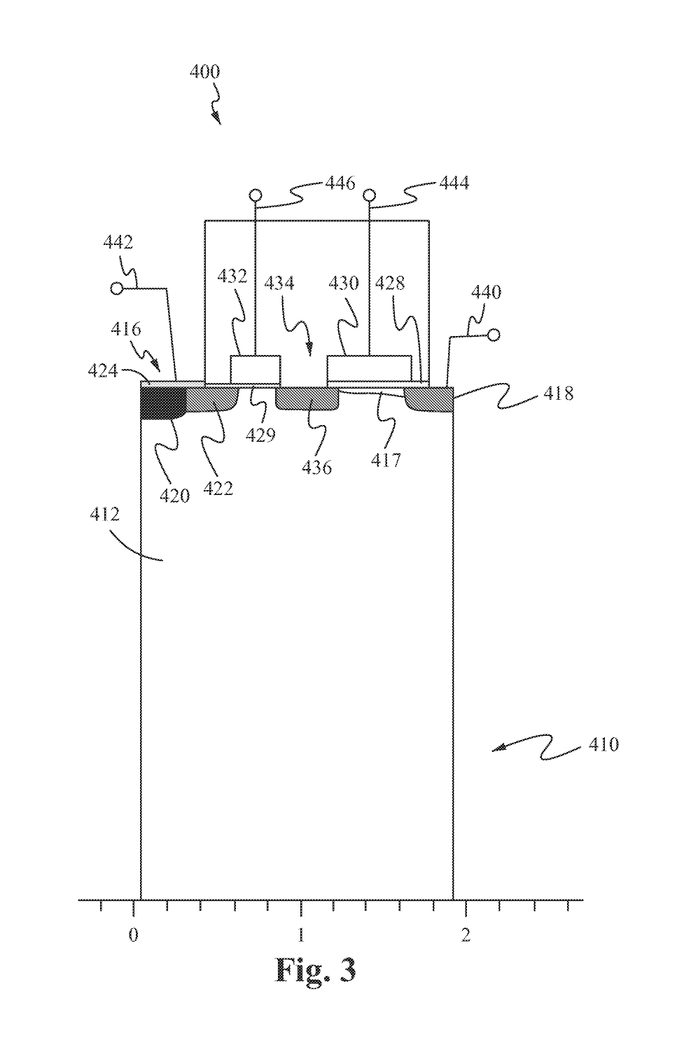

FIG. 3 illustrates a cut-out side view of a split gate laterally-configured power transistor 400 according to a first embodiment. In this example configuration, the power transistor 400 is a N-channel MOSFET. A substrate 410 is doped to form a P-type region 412, a P+ region 420, a N+ region 422 and a N+ region 418. The power transistor 400 includes a double diffused source 416 having a merged contact 424 between the P+ region 420 and the N+ region 422. The contact 424 shorts the P+ region 420 and the N+ region 422 together. The contact 424 functions as a source contact of the power transistor, and the source is shorted to the body of the substrate, which is P-type in this example configuration. A source contact terminal 442 is coupled to the contact 424, and therefore to the source 416. The N+ region 418 functions as the drain of the split gate power transistor. A drain contact terminal 440 is coupled to the drain 418.

In some embodiments, a lightly doped N-type region 417 is formed adjacent to the N+ region 418. The N-type region 417 is used to form a depletion mode MOSFET, as is described in detail below. In other embodiments, the region 417 is not doped with N-type and remains part of the P-type region 412.

A stepped gate oxide is formed on the top surface of the substrate 410. In some embodiments, the gate oxide layer is deposited using suitable semiconductor deposition processes. The stepped gate oxide includes two adjacent gate oxide layers having different thicknesses. A first gate oxide layer 429 has a thickness that is less than a thickness of a second gate oxide layer 428. The difference in thicknesses between the first gate oxide layer 429 and the second gate oxide layer 428 shown in FIG. 3 is for example purposes only to illustrate the relative difference in thicknesses between the two. In general, the dimensions and positions of each of the elements shown in the figures is for illustrative purposes only and may not be representative of the dimensions and positions in practice. In particular, the relative thicknesses shown for the first gate oxide layer 429 and the second gate oxide layer 428 compared to the other elements of the power transistor 400 are for example purposes only.

A polysilicon layer is formed over the stepped gate oxide layers. A slice of the polysilicon layer is removed, along with a portion of the stepped gate oxide layers underneath the slice of polysilicon layer, forming two electrically isolated polysilicon portions. The slice of the polysilicon layer is removed from above the P-type region 412. In some embodiments, the polysilicon portions are formed using suitable semiconductor deposition and etching processes. A first polysilicon portion forms a switching gate 430, which is positioned over the first gate oxide layer 429. A second polysilicon portion forms a static gate 432, which is positioned over the second gate oxide layer 428. The switching gate 430 and the static gate 432 are physically separated by a gap 434, which corresponds to the removed slice of polysilicon and the corresponding portion of stepped gate oxide underneath the removed slice of polysilicon. A doped bridge region 436, referred to as a bridge, is formed in the substrate below the gap 434. The bridge 436 is formed during fabrication of the switching gate 430 and the static gate 432. Fabricating the bridge 436 includes a doping step. During this doping step, a mask is applied that leaves the switching gate 430, the static gate 432, and the portion of substrate under the gap 434 exposed to dopant. As the dopant is applied, the doped bridge region 436 is formed at the exposed portion of the substrate. The switching gate 430, the static gate 432, and the bridge 436 are doped the same type as the source region 422, and the drain 418.

An insulating oxide 438 is applied which covers the switching gate 430 and the static gate 432. As shown in FIG. 3, the first gate oxide layer 429 between the switching gate 430 and the substrate 410, and the second gate oxide layer 428 between the static gate 432 and the substrate 410 are both thin oxide layers. The static gate 432 is electrically isolated from the switching gate 430 by the gap 434. In many applications, power transistors are laid out having many interdigitated stripes, for example a source stripe, a gate stripe, and a drain stripe. As applied to FIG. 3, a drain stripe functions as the drain contact terminal 440, and a source stripe functions as the source contact terminal 442. In the split gate power transistor, the switching gate and the static gate can also be laid out in stripes, separated by the gap. For example, a static gate stripe functions as a static gate contact terminal, schematically illustrated in FIG. 3 as static gate contact terminal 444, and the switching gate stripe functions as a switching gate contact terminal, schematically illustrated in FIG. 3 as switching gate contact terminal 446. In reference to FIG. 3, the stripes are oriented into and out of the plane of the page. If a gate is normally connected at the end of its stripe, which can be hundreds of microns long, the switching gate and the static gate can similarly extend as stripes, the ends of which can be electrically connected to a first voltage supply and a second voltage supply, respectively. Alternatively, the source, drain, switching gate, and/or static gate can be configured for electrical coupling along an entire width of the device, or along periodic contact points along the device width, where the width of the device is into and out of the page of FIG. 3. In these alternative configurations, one or more gaps can be cut into the oxide 438 to provide contact access points to the switching gate 430 and to the static gate 432. A gap is cut in the oxide 438 at each desired contact point or region.

There are two main regions in the substrate 410 relative to the operation of the split gate power transistor: a first channel region and a second channel region. The first channel region is formed underneath the switching gate 430 and in the P-type region 412 between the P+ region 422 and bridge region 436. The second channel region is formed underneath the static gate 132 and in the P-type region 412 between the bridge region 436 and the P+ region 418. The bridge 436 splits what would have been a single channel region in the P-type region 412 if the gap 434 and subsequent doping had not been formed. In the split gate power transistor, the bridge 436 splits this would be single channel region into two separately controllable channel regions, the first channel region and the second channel region. The position of the bridge 436, and therefore the gap 434, is far enough from the source region 422 so as to prevent punch-though from the source 422 to the bridge 436 when the device is in an off state. The bridge 436 is also positioned far enough from the drain region 418 so as to not negatively impact the breakdown voltage.

Compared to a comparable conventional power transistor that does not have a split gate configuration, such as the power transistor 52 in FIG. 1, the channel region of the power transistor 400 is lengthened to accommodate the bridge 436. In this regard, the power transistor 400 suffers from an increase in area. However, the doped N-type bridge region 436 is more conductive than if the same area were an inverted channel, as in the power transistor 52 (FIG. 1). As such, the carrier mobility in the N-type bridge region is improved, thereby reducing a portion of the on-resistance that was added by lengthening the channel region.

In operation, a first voltage supply is electrically coupled to the switching gate 430, schematically shown as terminal 444 in FIG. 3, and a second voltage supply is electrically coupled to the static gate 432, schematically shown as terminal 446 in FIG. 3. A constant voltage is applied to the static gate 432, thereby creating a conductive channel between the bridge 436 and the drain 418. In general, the constant voltage is large enough to create the conductive channel, but not large enough to rupture the thinner gate oxide 429 between the static gate 432 and the substrate 410. The constant voltage applied to the static gate 432 is the gate-to-drain voltage Vgd. A switching voltage is applied to the switching gate 430. The switching voltage alternates between a high, turn-on voltage and a low, turn-off voltage according to the switching frequency of the device. In an example application, the turn-off voltage is OV and the turn-on voltage is 2V. The switching voltage applied to the switching gate 432 is the gate-to-source voltage Vgs.

When the switching voltage is high, a conductive channel is created between the source N+ region 422 and the bridge 436, thereby turning-on the split gate power transistor. With the split gate power transistor turned on, current flows from the source 416 through the first channel formed underneath the switching gate 430 to the bridge 436, through the second channel formed underneath the static gate 432 to the drain 418. When the switching voltage is low, the current can not flow from the N+ region 422 to the bridge 436 since the conductive first channel region is not created, thereby turning-off the split gate power transistor.

The split gate power transistor 400 in FIG. 3 is an integrated combination of an enhancement-mode MOSFET operating at a first voltage and a depletion-mode MOSFET operating at a second voltage that is higher than the first voltage. The enhancement-mode MOSFET is comprised of the source 422, the gate 430, and the bridge 436. The depletion-mode MOSFET is comprised of the bridge 436, the gate 432, and the drain 418. In an example application, the enhancement-mode MOSFET is an enhancement-mode 2V MOSFET, and the depletion-mode MOSFET is a depletion-mode 5V MOSFET. As compared to the conventional switching gate, enhancement-mode 5V MOSFET in FIG. 1, the split gate power transistor 400 replaces the switching gate, enhancement-mode 5V MOSFET, which has a gate length of 0.6 um and a gate oxide thickness of 14 nm, with a switching gate, enhancement-mode 2V MOSFET, which has a gate length of 0.18 um and a gate oxide thickness of 4 nm. The voltage swing required for the switching gate, enhancement-mode 2V MOSFET to go from fully off to fully on is only 2V, instead of 5V. To ensure that the thin gate oxide 429 under the switching gate 430 is not damaged by putting more than 2V across it, the depletion-mode 5V MOSFET with the thicker gate oxide 428 is positioned between the switching gate 430 and the drain 418 of the split gate power transistor 400. The depletion-mode 5V MOSFET has the same gate length and gate oxide thickness as the switching gate, enhancement-mode 5V MOSFET. The depletion-mode 5V MOSFET can be extremely leaky since it is in series with a 2V MOSFET, and thus the gate length of the depletion-mode 5V MOSFET can be as short as a conventional enhancement-mode 5V MOSFET. The gate 432 of the depletion-mode 5V MOSFET is not switched, but is coupled to a DC supply that is 2V above the voltage at the source 422 of the enhancement-mode 2V MOSFET. In general, the bias voltage applied to the gate 432 can not exceed the breakdown voltage of the first gate oxide 429. Because of the smaller gate voltage swing of the switching gate 432, 2V versus 5V in the conventional case, and also because of the smaller length of the switching gate 432, the gate charge is considerably reduced compared to a conventional switching gate, enhancement-mode 5V MOSFET as in FIG. 1.

To realize an advantage, it is important that not only the gate charge per unit width is reduced, but that the product of gate charge and on-resistance is reduced, ideally without increasing the specific on-resistance too much. When the split gate power transistor is switching, the static gate should be biased to no more than the rated voltage of the switching gate, for example 2V, such that the bridge, which functions as the drain of the switching gate, is maintained below the maximum voltage, for example 2V, imposed by the thinner gate oxide thickness below the switching gate. If the threshold voltage of the depletion-mode MOSFET is low enough, for example −2V, then the resistance contribution of the depletion-mode MOSFET is relatively close to the resistance of the conventional enhancement-mode MOSFET with the same channel length.

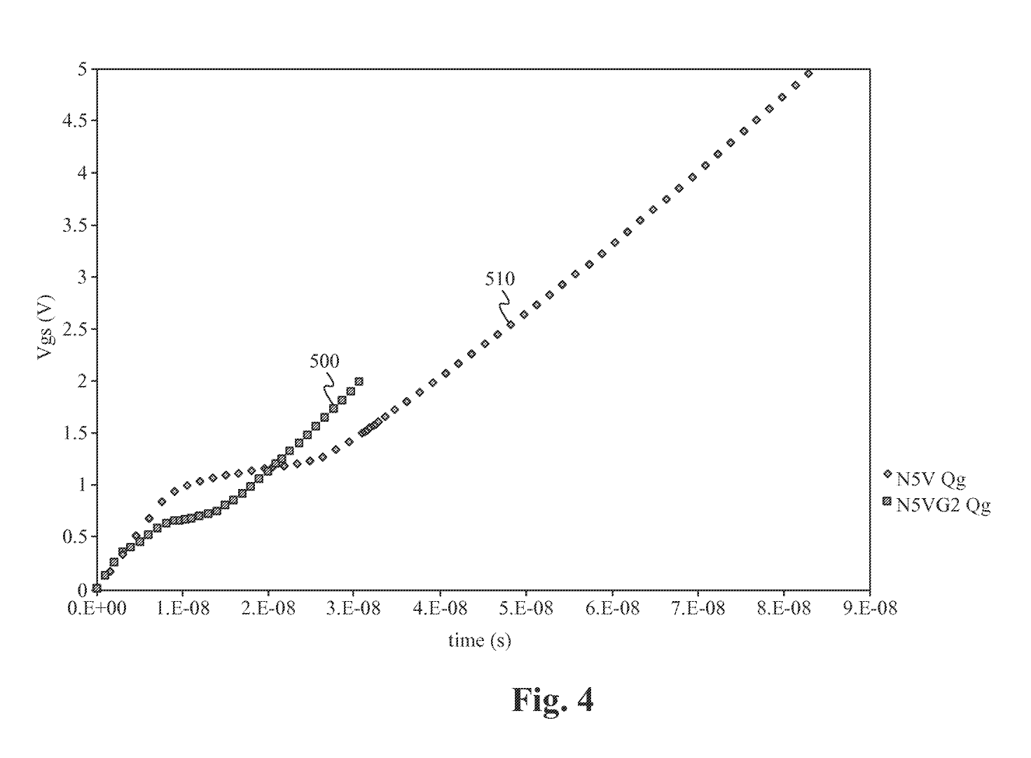

FIG. 4 illustrates a gate charge curve for a power MOSFET, such as that shown in FIG. 1, and the first embodiment of the split gate power MOSFET, such as that of FIG. 3. The gate charge curve is a common figure of merit for MOSFETs. To determine the gate charge, the drain is connected to a nominal supply voltage through a load resistance, the source is grounded, and the gate is grounded. As applied to the split gate configuration, reference to the “gate” in the context of determining the gate charge curve of FIG. 4 refers to the switching gate; the static gate remains connected to its DC potential. A constant current is forced into the gate, and the gate-to-source voltage Vgs is measured. As the supply voltage is applied to the gate, the gate-to-source voltage Vgs starts to rise until the threshold voltage is reached, which is 1.5V in this example. The threshold voltage corresponds to the flat portion of the curve, which is where the power transistor begins to turn on. When the gate-to-source voltage Vgs reaches the fully rated voltage, which is 5V in this example, the trace is stopped. The gate charge is determined as the integration of the measured voltage. In the example shown in FIG. 4, the gate charge curves are measured for the conventional switching gate, enhancement-mode 5V MOSFET having a rated gate-to-source voltage of 5V and an operating voltage of 24V, and the split gate configuration with the switching gate, enhancement mode 2V MOSFET having a rated gate-to-source voltage of 2V and operating voltage of 24V in series with the static gate, depletion-mode 5V MOSFET biased to 2V on the static gate. In general, the operating voltage range is 14V to 60V without having to increase the footprint of the polysilicon that forms the active gate and the field plate of the split gate power transistor.

The curve 500 is the gate charge curve of the split gate power transistor of FIG. 3, and the curve 510 is for a power transistor, such as the power transistor of FIG. 1. Note that the split gate power transistor is fully enhanced at 2V, so the gate charge curve 500 ends at 2V Vgs. It is seen in FIG. 4 that the gate charge of the split gate power transistor is reduced compared to the power transistor. Reducing the size of the active gate, by removing the slice of polysilicon, reduces the gate charge. The active polysilicon gate and the static gate are electrically isolated so that the charge that effects the active gate is reduced to the lowest possible level.

It can also be seen that the relatively flat portion of the curve 500 is reduced compared to the relatively flat portion of the curve 510. The flat portion represents the gate-to-drain charge Qgd, which is the integral of the gate-to-drain voltage across the flat region. Within the flat region, more and more current is forced into the gate, but the gate-to-source voltage remains substantially constant.

The split gate power transistor provides a reduction in the product of on-resistance (R) and gate charge (Qg). An on-resistance of the power MOSFET is the resistance between the drain and the source while the transistor is turned on. However, there is an increase in the product of on-resistance (R) and gate area (A), referred to as the specific on-resistance. The specific on-resistance provides a conceptual measure of the size of the power transistor. The specific on-resistance of the split gate configuration rises compared to a comparable conventional power transistor that does not have a split gate configuration, such as the power transistor 52 in FIG. 1, because the channel region of the power transistor 400 is lengthened to accommodate the bridge 436. In this regard, the power transistor 400 suffers from an increase in gate area, which result in an increase in the on-resistance (R) times gate area (A) product. However, the doped N-type bridge region 436 is more conductive than if the same area were an inverted channel, as in the power transistor 52 (FIG. 1). As such, the carrier mobility in the N-type bridge region 436 is improved, thereby reducing a portion of the increased R*A product resulting from lengthening the channel region.

In an example application, accounting for all effects related to the split gate configuration there is an approximate 63% reduction in the gate charge Qg, an approximate 59% reduction in the R*Qg product, and an approximate 23% increase in the R*A product compared to comparable conventional power transistor that does not have the split gate configuration. In this example case, the gate charge per unit width is 37% of the conventional power transistor.

The following highlight some of the properties of the first embodiment of the split gate power transistor, especially as compared to a comparable power transistor. First, the gate capacitance and the gate charge are reduced because the switching portion of the gate, the switching gate, has a smaller gate area. Second, because a smaller switching gate is used, which used a smaller switching voltage, the gate-to-drain feedback capacitance is reduced. This further reduces the gate charge compared to a comparable power transistor because during switching, the gate-to-drain capacitance is amplified by the Miller effect. Third, switch mode power supply (SMPS) efficiency is improved. Fourth, the process of fabricating the split gate power transistor is CMOS compatible. As such, the split gate power transistor can be fabricated monolithically with CMOS devices, including the output circuits of a SMPS. Fabrication of a power MOSFET on the same integrated circuit as the SMPS circuit results in smaller overall SMPS system size and cost.

The split gate power transistor 400 is shown and described above as having a depletion-mode static gate transistor. In alternative embodiments, the static gate transistor is configured in enhancement-mode. In general, the split gate power transistor can be configured with the static gate configured in either enhancement-mode or depletion-mode as long as the overall design does not allow the voltage at the bridge 436 to reach the breakdown voltage of the first gate oxide 429.

The split gate power transistor can be adapted for higher voltage applications. Embodiments of a higher voltage split gate power transistor include a laterally configured power MOSFET having a doped silicon substrate, a gate oxide layer formed on a surface of the substrate, and a split polysilicon layer formed over the gate oxide layer. The polysilicon layer is cut into two electrically isolated portions, a first portion forming a polysilicon switching gate positioned over a first channel region of the substrate, and a second portion forming a polysilicon static gate formed over a second channel region and a transition region of the substrate. The first channel region and the second channel region are bridged by a doped bridge region in the substrate. The bridge is doped the same type as the source and the drain. A portion of the static gate extends over a drift region of the substrate, where the drift region is under a field oxide filled trench formed in the substrate. The extended portion of the static gate functions as a field plate to establish a high breakdown voltage. The switching gate is electrically coupled to a first voltage source and the static gate is electrically coupled to a second voltage source. In an example application, a constant voltage is applied to the static gate, and a high frequency switching voltage is applied to the switching gate. The constant voltage applied to the static gate is large enough to establish an inversion layer in the second channel region below the static gate. With the constant voltage applied, the static gate functions as the field plate.

The polysilicon layer is cut over a channel region, or body, of the MOSFET. The substrate includes a doped bridge region, referred to as a bridge, that splits the channel region to form the first channel region and the second channel region. The bridge is formed during fabrication of the switching gate and the static gate. When the polysilicon layer is cut, a portion of the substrate is exposed where the cut portion of the polysilicon is removed. The two polysilicon portions and the exposed portion of substrate are doped. During this doping process, the doped bridge region is formed at the exposed portion of the substrate. The bridge splits the would be channel region into the first channel region and the second channel region. The first channel region is positioned between the source and the bridge. The second channel region is positioned between the bridge and the transition region.

In conventional power MOSFETs, such as that shown in FIG. 1, a significant component of the gate capacitance is due to the gate-to-drain capacitance at the transition region. Applying a switching voltage to the gate amplifies the gate-to-drain capacitance due to the Miller effect. In the split gate power transistor, the switching portion of the gate, the switching gate, is isolated to the channel region, while the portion of the gate over the transition region, the static gate, remains at a constant voltage. This reduces, if not eliminates, the Miller capacitance between the gate and the drain. Also, by reducing the area of the switching gate, the amount of charge, the gate charge, transferred during each switching cycle is reduced.

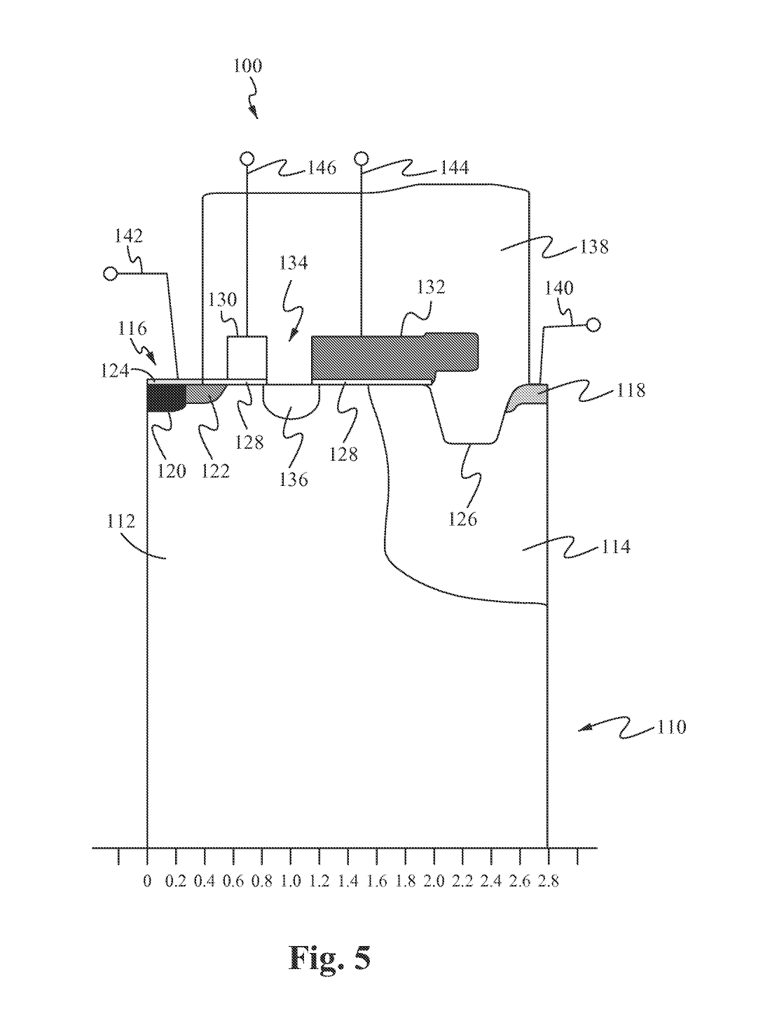

FIG. 5 illustrates a cut-out side view of a split gate laterally-configured power transistor 100 according to a second embodiment. In this example configuration, the power transistor 100 is a N-channel double-diffused MOSFET (N-channel DMOSFET). The substrate 110 is doped to form a P-type region 112 and a N-type region 114. The P-type region 112 includes a double-diffused source 116 having a merged contact 124 between a P+ region 120 and a N+ region 122. The contact 124 shorts the P+ region 120 and the N+ region 122 together. The contact 124 functions as a source contact of the split gate power transistor, and the source is shorted to the body of the substrate, which is P-type. The P-type region extends across the entire width of the lower portion of the substrate 110, including underneath the N-type region 114 on the right hand side of FIG. 5. A source contact terminal 142 is coupled to the contact 124, and therefore to the source 116. The substrate 110 is also doped to form a N+ region 118 within the N-type region 114. The N+ region 118 functions as the drain of the split gate power transistor. A drain contact terminal 140 is coupled to the drain 118. A trench 126 is formed in a top surface of the substrate 110. The trench 126 is filled with field oxide. In some embodiments, the trench 126 is formed using a Shallow Trench Isolation (STI) process, and the field oxide filled trench is referred to as a STI region. In other embodiments, the trench 126 is formed using any suitable semiconductor fabrication technique capable of removing a portion of the substrate used to form a thick field oxide region.

A gate oxide 128 is formed on the top surface of the substrate 110. In some embodiments, the gate oxide layer is deposited using suitable semiconductor deposition processes. A polysilicon layer is formed over the gate oxide 128. A slice of the polysilicon layer is removed, forming two electrically isolated polysilicon portions. The slice of the polysilicon layer is removed from above the P-type region 112. In some embodiments, the polysilicon portions are formed using suitable semiconductor deposition and etching processes. A first polysilicon portion forms a switching gate 130. A second polysilicon portion forms a static gate 132. The switching gate 130 and the static gate 132 are physically separated by a gap 134, which corresponds to the removed slice of polysilicon and removed portion of the gate oxide 128. A doped bridge region 136, referred to as a bridge, is formed in the substrate below the gap 134. The bridge 136 is formed during fabrication of the switching gate 130 and the static gate 132. Fabricating the switching gate 130 and the static gate 132 includes a doping step. During this doping step, a mask is applied that leaves the switching gate 130, the static gate 132, and the portion of substrate under the gap 134 exposed to dopant. As the dopant is applied, the doped bridge region 136 is formed at the exposed portion of the substrate. The switching gate 130, the static gate 132, and the bridge 136 are doped the same type as the source region 122, and the drain 118.

An insulating oxide 138 is applied which covers the switching gate 130 and the static gate 132. As shown in FIG. 5, the gate oxide layer 128 between the switching gate 130 and the substrate 110, and the gate oxide layer 128 between the static gate 132 and the substrate 110 is a thin oxide layer of the same thickness. The static gate 132 is electrically isolated from the switching gate 130 by the gap 134. In many applications, power transistors are laid out having many interdigitated stripes, for example a source stripe, a gate stripe, and a drain stripe. For example, the drain stripe functions as the drain contact terminal 140, and the source stripe functions as the source contact terminal 142. In the split gate power transistor, the switching gate and the static gate can also be laid out in stripes, separated by the gap. For example, the static gate stripe functions as a static gate contact terminal, schematically illustrated in FIG. 5 as static gate contact terminal 144, and the switching gate stripe functions as a switching gate contact terminal, schematically illustrated in FIG. 5 as switching gate contact terminal 146. In reference to FIG. 5, the stripes are oriented into and out of the plane of the page. If a gate is normally connected at the end of its stripe, which can be hundreds of microns long, the switching gate and the static gate can similarly extend as stripes, the ends of which can be electrically connected to a first voltage supply and a second voltage supply, respectively. Alternatively, the source, drain, switching gate, and/or static gate can be configured for electrical coupling along an entire width of the device, or along periodic contact points along the device width, where the width of the device is into and out of the page of FIG. 5. In these alternative configurations, one or more gaps can be cut into the oxide 138 to provide contact access points to the switching gate 130 and to the static gate 132. A gap is cut in the oxide 138 at each desired contact point or region.

The static gate 132 extends over the field oxide filled trench 126 to support high gate-to-drain voltage. The static gate 132 is necessary to maintain a higher breakdown voltage. If the static gate is not extended over the trench 126, or the trench 126 itself is removed, the breakdown voltage suffers. In this case, almost all the gate-to-drain voltage is dropped across the thin gate oxide, which does not enable the power transistor to meet the rated voltage.

There are four main regions in the substrate 110 relative to the operation of the split gate power transistor: a first channel region, a second channel region, a transition region, and a drift region. The first channel region is formed underneath the switching gate 130 and in the P-type region 112 of the substrate 110. The second channel region is formed underneath the static gate 132 and in the P-type region 112 of the substrate 110. In other words, the second channel region is formed where the static gate 132 overlaps the P-type region 112. The bridge 136 splits what would have been a single channel region in the P-type region 112 if the gap 134 had not been formed. In the split gate power transistor, the bridge 136 splits this would be single channel region into two separately controllable channel regions, the first channel region and the second channel region. The first channel region is positioned between the source region 122 and the bridge 136. The second channel region is positioned between the bridge 136 and the transition region. The position of the bridge 136, and therefore the gap 134, is far enough from the source region 122 so as to prevent punch-though from the source 122 to the bridge 136 when the device is in an off state. The bridge is also positioned far enough from the P-N junction between the second channel region and the transition region so as to not negatively impact the breakdown voltage.

The drift region is the portion of the N-type region 114 underneath the trench 126, or the STI region. The drift region is necessary to support a high gate-to-drain voltage. If the static gate 132 were to instead terminate over the thin gate oxide, this would result in too high a voltage over the gate oxide and the split gate power transistor would not function. As such, the STI region and the static gate extension over the STI region are necessary to drop the high gate-to-drain voltage. The transition region is the portion of the N-type region 114 underneath the static gate 132. The transition region is also referred to as the accumulation region or the neck region.

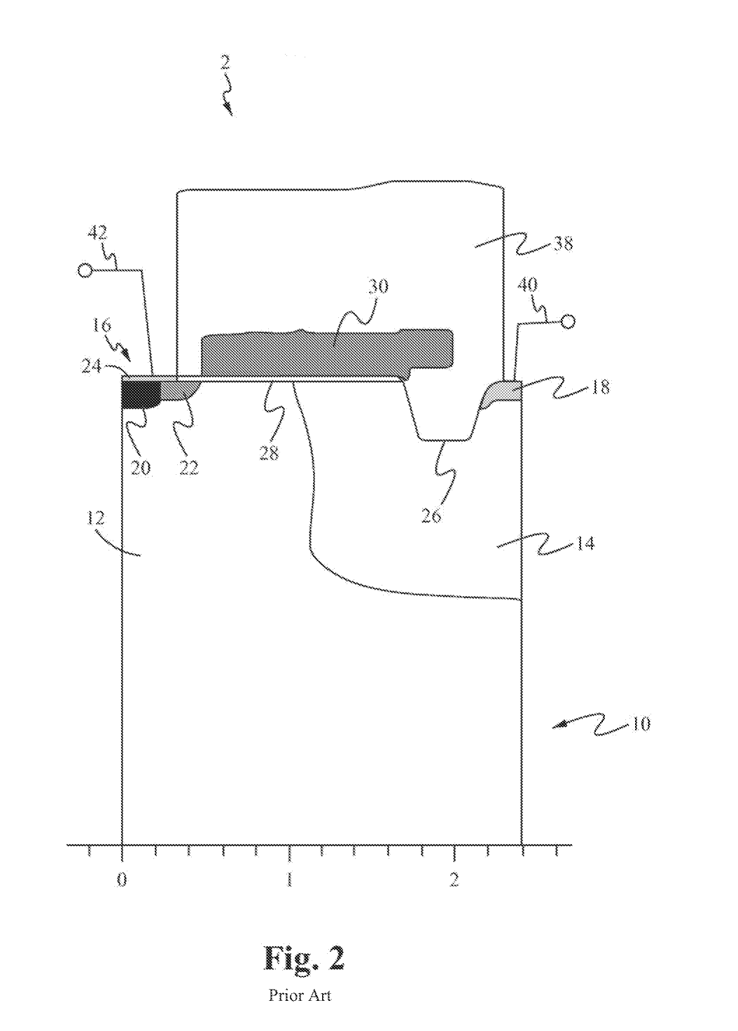

Compared to a comparable conventional power transistor that does not have a split gate configuration, such as the power transistor 2 in FIG. 2, the channel region of the power transistor 100 is lengthened to accommodate the bridge 136. In this regard, the power transistor 200 suffers from an increase in area. However, the doped N-type bridge region 136 is more conductive than if the same area were an inverted channel, as in the power transistor 2 (FIG. 2). As such, the carrier mobility in the N-type bridge region is improved, thereby reducing a portion of the on-resistance that was added by lengthening the channel region.

In operation, a first voltage supply is electrically coupled to the switching gate 130, schematically shown as terminal 146 in FIG. 5, and a second voltage supply is electrically coupled to the static gate 132, schematically shown as terminal 144 in FIG. 5. A constant voltage is applied to the static gate 132, thereby creating a conducive channel between the bridge 136 and the transition region. With the constant voltage applied, the portion of the static gate 132 that extends over the trench 126 also functions as a field plate. In an example application, the constant voltage is 5V. In general, the constant voltage is large enough to create the conductive channel, but not large enough to rupture the gate oxide between the static gate 132 and the substrate 110. The constant voltage applied to the static gate 132 is the gate-to-drain voltage Vgd. A switching voltage is applied to the switching gate 130. The switching voltage alternates between a high, turn-on voltage and a low, turn-off voltage according to the switching frequency of the device. In an example application, the turn-off voltage is OV and the turn-on voltage is 5V. The switching voltage applied to the switching gate 132 is the gate-to-source voltage Vgs.

When the switching voltage is high, a conductive channel is created between the source N+ region 122 and the bridge 136, thereby turning-on the power transistor. With the power transistor turned on, current flows from the source 116 through the first channel formed underneath the switching gate 130 to the bridge 136, through the second channel formed underneath the static gate 132 to the transition region, and through the transition region and drift region to the drain 118. The transition region and the drift region provide a current flow path from the second channel region to the drain 118 when the split gate power transistor is turned-on. When the switching voltage is low, the current can not flow from the N+ region 122 to the bridge 136 since the conductive first channel region is not created, thereby turning-off the transistor.

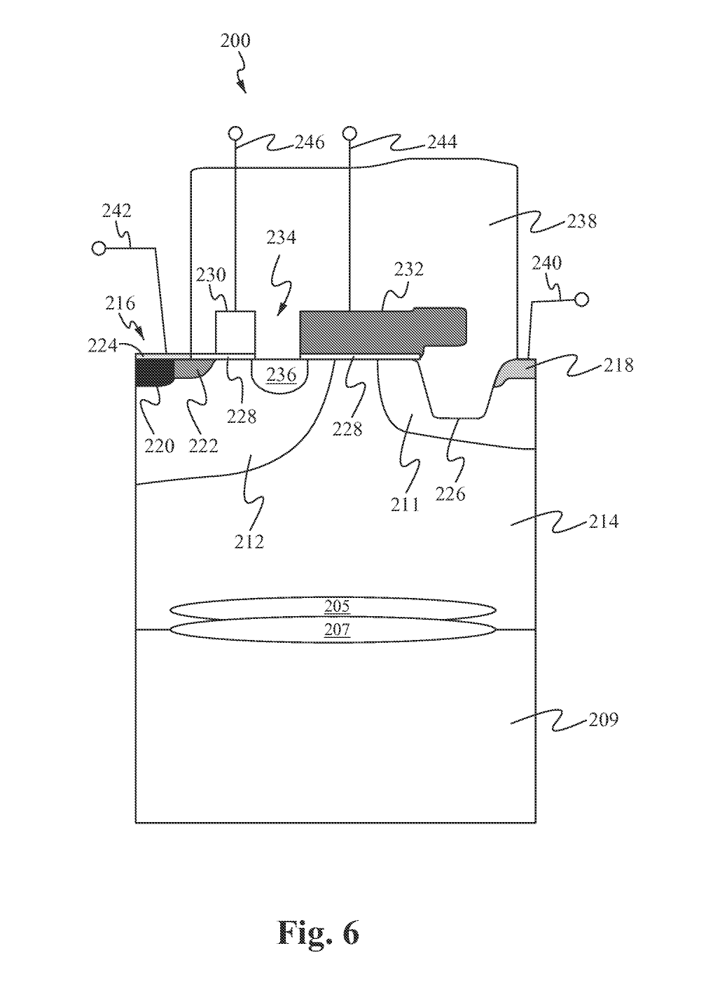

FIG. 6 illustrates a cut-out side view of a split gate laterally-configured power transistor 200 according to a second embodiment. The power transistor 200 is configured similarly as the power transistor 100 of FIG. 5 except that the substrate is doped differently. The power transistor 200 includes a P-type substrate 209, a N-type buried layer (NBL) 207, a P-type region 205, a N-type region 214, a N-type region 211, and a P-type region 212. The P-type region 212 is comparable to the P-type region 112 of power transistor 100 in that the P-type region 212 includes a N+ bridge region 236 and a double-diffused source having a merged contact between a P+ region 220 and a N+ region 222. In operation, first and second conductive channel regions are formed in a manner similar to the power transistor 100.

The N-type region 214 extends across the entire width of the substrate, including underneath the P-type region 212 on the left hand side of FIG. 6. The N-type region 214 has a relatively lower N-type concentration than the N-type region 211, and the N-type region 211 has a relatively lower N-type concentration than the drain 218. The NBL 207 has a relatively higher N-type concentration than the N-type region 214. The P-type region 205 is surrounded on all side by N-type material, the N-type region 214 and the NBL 207. In this manner, the P-type region 205 is electrically isolated from the P-type substrate 209. The presence of the P-type region 205 enables a higher doped concentration of the N-type region 211 without lowering the breakdown voltage. Since the N-type region 211 is more highly concentrated than the N-type region 214, most of the current flows from the transition region to the drain 218 through the N-type region 211. As a result, the on-resistance is influenced by the N-type concentration in the N-type region 211. Enabling a more highly doped concentration in the N-type region 211 enables a manner of lowering the on-resistance without effecting the rest of the transistor. In other words, increasing the N-type concentration in the N-type region 211 reduces the on-resistance.

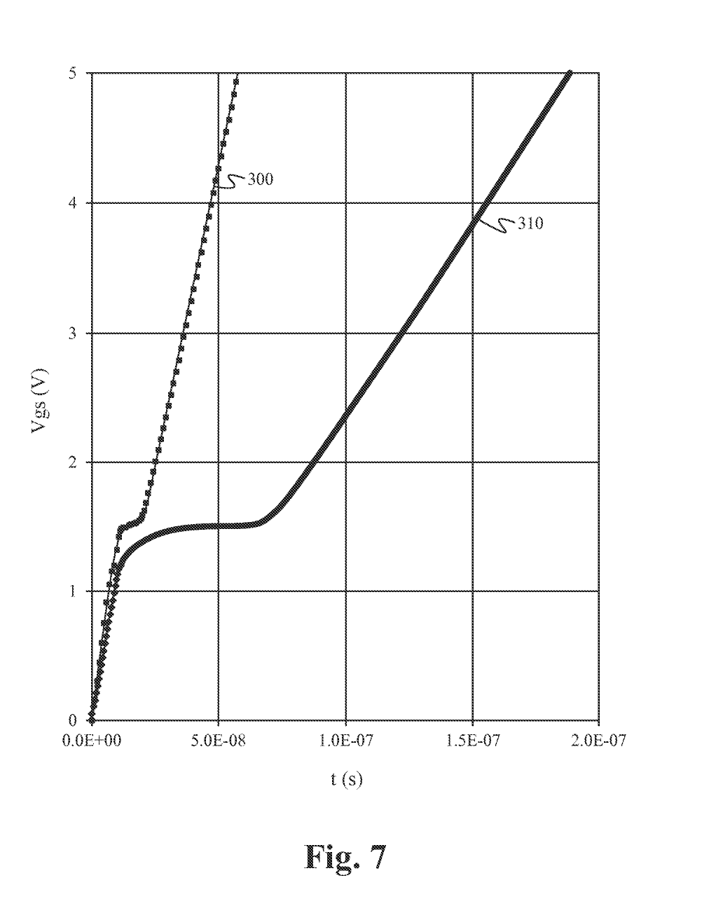

FIG. 7 illustrates a gate charge curve for a conventional power MOSFET, such as that shown in FIG. 2, and the split gate power MOSFET, such as that of FIG. 5. The gate charge curve is a common figure of merit for MOSFETs. To determine the gate charge, the drain is connected to a nominal supply voltage through a load resistance, the source is grounded, and the gate is grounded. A constant current is forced into the gate, and the gate-to-source voltage Vgs is measured. As the supply voltage is applied to the gate, the gate-to-source voltage Vgs starts to rise until the threshold voltage is reached, which is 1.5V in this example. The threshold voltage corresponds to the flat portion of the curve, which is where the power transistor begins to turn on. When the gate-to-source voltage Vgs reaches the fully rated voltage, which is 5V in this example, the trace is stopped. The gate charge is determined as the integration of the measured voltage. In the example shown in FIG. 7, the gate charge curves are measured for power MOSFETS having a rated gate-to-source voltage of 5V and an operating voltage of 24V. In general, the operating voltage range is 14V to 60V without having to increase the footprint of the polysilicon that forms the active gate and the field plate of the split gate power transistor.

The curve 300 is the gate charge curve of the split gate power transistor of FIG. 5, and the curve 310 is for a similar conventional power transistor, such as the power transistor of FIG. 2. It is seen in FIG. 7 that the gate charge of the split gate power transistor is reduced compared to the conventional power transistor. Reducing the size of the active gate, by removing the slice of polysilicon, reduces the gate charge. It is still necessary to prevent the breakdown of the split gate power transistor, which is accomplished using the field plate. The active polysilicon gate and the field plate are electrically isolated so that the charge that effects the active gate is reduced to the lowest possible level.

It can also be seen that the flat portion of the curve 300 is reduced compared to the flat portion of the curve 310. The flat portion represents the gate-to-drain charge Qgd, which is the integral of the gate-to-drain voltage across the flat region. Within the flat region, more and more current is forced into the gate, but the gate-to-source voltage remains constant.

The gate-to-drain charge Qgd is related to the feedback capacitance between the drain and the gate. In general, the portion of the gate that is positioned over the drain well is amplified and has more of an effect on the gate charge than the portion of the gate that is over the source well. By splitting the polysilicon gate into the switching gate and the static gate, and applying a constant voltage to the static gate, which is the only gate portion positioned over the drain well, the feedback capacitance related to the Miller effect is reduced if not eliminated.

The split gate power transistor provides a reduction in the product of on-resistance (R) and gate charge (Qg). An on-resistance of the power MOSFET is the resistance between the drain and the source while the transistor is turned on. However, there is a slight increase in the product of on-resistance (R) and gate area (A), referred to as the specific on-resistance. The specific on-resistance provides a conceptual measure of the size of the power transistor. The specific on-resistance of the split gate configuration rises compared to a comparable conventional power transistor that does not have a split gate configuration, such as the power transistor 2 in FIG. 2, because the channel region of the power transistor 100 (or 200) is lengthened to accommodate the bridge 136. In this regard, the power transistor 100 suffers from an increase in gate area, which result in an increase in the on-resistance (R) times gate area (A) product. However, the doped N-type bridge region 136 is more conductive than if the same area were an inverted channel, as in the power transistor 2 (FIG. 2). As such, the carrier mobility in the N-type bridge region 136 is improved, thereby reducing a portion of the increased R*A product resulting from lengthening the channel region.

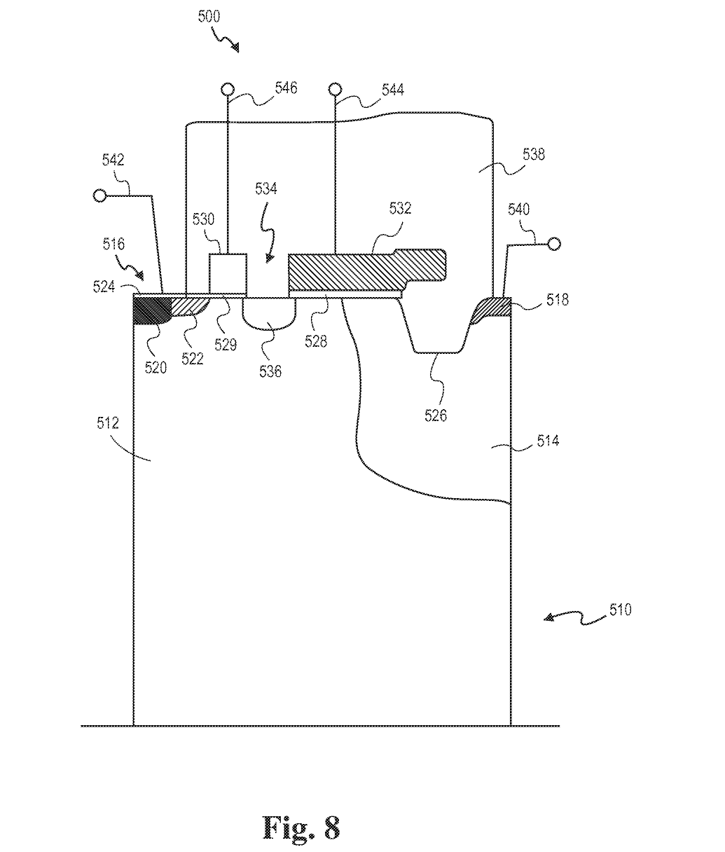

FIG. 8 illustrates a cut-out side view of a split gate laterally-configured power transistor 500 according to another embodiment of the present disclosure. In this example configuration, the power transistor 500 is an N-channel double-diffused MOSFET (N-channel DMOSFET). The substrate 510 is doped to form a P-type region 512 and an N-type region 514. The P-type region 512 includes a double-diffused source 516 having a merged contact 524 between a P+ region 520 and an N+ region 522. The contact 524 shorts the P+ region 520 and the N+ region 522 together. The contact 524 functions as a source contact of the split gate power transistor, and the source is shorted to the body of the substrate, which is P-type. The P-type region extends across the entire width of the lower portion of the substrate 510, including underneath the N-type region 514 on the right hand side of FIG. 8. A source contact terminal 542 is coupled to the contact 524, and therefore to the source 516. The substrate 510 is also doped to form an N+ region 518 within the N-type region 514. The N+ region 518 functions as the drain of the split gate power transistor. A drain contact terminal 540 is coupled to the drain 518. A trench 526 is formed within the substrate 510. The trench 526 is filled with field oxide. In some embodiments, the trench 526 is formed using a Shallow Trench Isolation (STI) process, and the field oxide filled trench is referred to as a STI region. In other embodiments, the trench 526 is formed using any conventional semiconductor fabrication technique capable of removing a portion of the substrate used to form a thick field oxide region.

A stepped gate oxide is formed over the top surface of the substrate 510. In some embodiments, the gate oxide layer is deposited using suitable semiconductor deposition processes. The stepped gate oxide includes two adjacent gate oxide layers having different thicknesses. A first gate oxide layer 529 has a thickness that is less than a thickness of a second gate oxide layer 528. The difference in thicknesses between the first gate oxide layer 529 and the second gate oxide layer 528 shown in FIG. 8 is for illustration purposes to illustrate the relative difference in thicknesses between the two oxide layers 528, 529. In general, the dimensions and positions of each of the elements shown in the figures is for illustrative purposes only and may not be representative of the dimensions and positions in practice. In particular, the relative thicknesses shown for the first gate oxide layer 529 and the second gate oxide layer 528 compared to the other elements of the power transistor 500 are for example purposes only. An insulating oxide 538 can be applied which covers the switching gate 530 and the static gate 532.

A polysilicon layer is formed over the stepped gate oxide layers. A slice of the polysilicon layer is removed, along with a portion of the stepped gate oxide layers underneath the slice of polysilicon layer, forming two electrically isolated polysilicon portions. The slice of the polysilicon layer is removed from above the P-type region 512. In some embodiments, the polysilicon portions are formed using suitable semiconductor deposition and etching processes. A first polysilicon portion forms a switching gate 530, which is positioned over the first gate oxide layer 529. A second polysilicon portion forms a static gate 532, which is positioned over the second gate oxide layer 528. The switching gate 530 and the static gate 532 are physically separated by a gap 534, which corresponds to the removed slice of polysilicon and the corresponding portion of stepped gate oxide underneath the removed slice of polysilicon. A doped bridge region 536, referred to as a bridge, is formed in the substrate below the gap 534. The bridge 536 is formed during fabrication of the switching gate 530 and the static gate 532. Fabricating the bridge 536 includes a doping step. During this doping step, a mask is applied that leaves the switching gate 530, the static gate 532, and the portion of substrate under the gap 534 exposed to dopant. As the dopant is applied, the doped bridge region 536 is formed at the exposed portion of the substrate. The switching gate 530, the static gate 532, and the bridge 536 are doped the same type as the source region 522, and the drain 518.

In many applications, power transistors are laid out having many interdigitated stripes, for example a source stripe, a gate stripe, and a drain stripe. For example, the drain stripe functions as the drain contact terminal 540, and the source stripe functions as the source contact terminal 542. In the split gate power transistor, the switching gate and the static gate can also be laid out in stripes, separated by the gap. For example, the static gate stripe functions as a static gate contact terminal, schematically illustrated in FIG. 8 as static gate contact terminal 544, and the switching gate stripe functions as a switching gate contact terminal, schematically illustrated in FIG. 8 as switching gate contact terminal 546. In reference to FIG. 8, the stripes are oriented into and out of the plane of the page. If a gate is normally connected at the end of its stripe, which can be hundreds of microns long, the switching gate and the static gate can similarly extend as stripes, the ends of which can be electrically connected to a first voltage supply and a second voltage supply, respectively. In another implementation, the source, drain, switching gate, and/or static gate can be configured for electrical coupling along an entire width of the device, or along periodic contact points along the device width, where the width of the device is into and out of the page of FIG. 8. In these implementations, one or more gaps can be cut into the oxides 528, 529 to provide contact access points to the switching gate 530 and to the static gate 532. A gap may be formed in the oxides 528, 529 at each desired contact point or region.

The static gate 532 extends over the field oxide filled trench 526 to support high gate-to-drain voltage. The static gate 532 is necessary to maintain a higher breakdown voltage. If the static gate is not extended over the trench 526, or the trench 526 itself is removed, the breakdown voltage suffers. In this case, almost all the gate-to-drain voltage is dropped across the thin gate oxide, which does not enable the power transistor to meet the rated voltage.

There are four main regions in the substrate 510 relative to the operation of the split gate power transistor: a first channel region, a second channel region, a transition region, and a drift region. The first channel region is formed underneath the switching gate 530 and in the P-type region 512 of the substrate 510. The second channel region is formed underneath the static gate 532 and in the P-type region 512 of the substrate 510. In other words, the second channel region is formed where the static gate 532 overlaps the P-type region 512. The bridge 536 splits what would have been a single channel region in the P-type region 512 if the gap 534 had not been formed. In the split gate power transistor, the bridge 536 splits this would be single channel region into two separately controllable channel regions, the first channel region and the second channel region. The first channel region is positioned between the source region 522 and the bridge 536. The second channel region is positioned between the bridge 536 and the transition region. The position of the bridge 536, and therefore the gap 534, is far enough from the source region 522 so as to prevent punch-though from the source 522 to the bridge 536 when the device is in an off state. The bridge is also positioned far enough from the P-N junction between the second channel region and the transition region so as to not negatively impact the breakdown voltage.

The drift region is the portion of the N-type region 514 underneath the trench 526, or the STI region. The drift region is necessary to support a high gate-to-drain voltage. If the static gate 532 were to instead terminate over the thin gate oxide, this would result in too high a voltage over the gate oxide and the split gate power transistor would not function. As such, the STI region and the static gate extension over the STI region are necessary to drop the high gate-to-drain voltage. The transition region is the portion of the N-type region 514 underneath the static gate 532. The transition region is also referred to as the accumulation region or the neck region.

Compared to a comparable conventional power transistor that does not have a split gate configuration, such as the power transistor 2 in FIG. 2, the channel region of the power transistor 100 is lengthened to accommodate the bridge 136. In this regard, the power transistor 200 suffers from an increase in area. However, the doped N-type bridge region 136 is more conductive than if the same area were an inverted channel, as in the power transistor 2 (FIG. 2). As such, the carrier mobility in the N-type bridge region is improved, thereby reducing a portion of the on-resistance that was added by lengthening the channel region.

In operation, a first voltage supply is electrically coupled to the switching gate 130, schematically shown as terminal 146 in FIG. 5, and a second voltage supply is electrically coupled to the static gate 132, schematically shown as terminal 144 in FIG. 5. A constant voltage is applied to the static gate 132, thereby creating a conducive channel between the bridge 136 and the transition region. With the constant voltage applied, the portion of the static gate 132 that extends over the trench 126 also functions as a field plate. In an example application, the constant voltage is 5V. In general, the constant voltage is large enough to create the conductive channel, but not large enough to rupture the gate oxide between the static gate 132 and the substrate 110. The constant voltage applied to the static gate 132 is the gate-to-drain voltage Vgd. A switching voltage is applied to the switching gate 130. The switching voltage alternates between a high, turn-on voltage and a low, turn-off voltage according to the switching frequency of the device. In an example application, the turn-off voltage is OV and the turn-on voltage is 5V. The switching voltage applied to the switching gate 132 is the gate-to-source voltage Vgs.

When the switching voltage is high, a conductive channel is created between the source N+ region 122 and the bridge 136, thereby turning-on the power transistor. With the power transistor turned on, current flows from the source 116 through the first channel formed underneath the switching gate 130 to the bridge 136, through the second channel formed underneath the static gate 132 to the transition region, and through the transition region and drift region to the drain 118. The transition region and the drift region provide a current flow path from the second channel region to the drain 118 when the split gate power transistor is turned-on. When the switching voltage is low, the current cannot flow from the N+ region 122 to the bridge 136 since the conductive first channel region is not created, thereby turning-off the transistor.

When the split gate power transistor is turned completely on, for example when the constant voltage applied to the static gate is 5V and the switching voltage applied to the switching gate is high, the current flows through the first channel region, the bridge, and the second channel region, through the transistor region and the drift region, which is under the field oxide filled trench, and back up to the N+ drain. Due to the constant voltage at the static gate, which covers the transition region, electrons accumulate in the transition region.

In an example application, accounting for all effects related to the split gate configuration there is an approximate 65% reduction in the R*Qg product, and an approximate 55% increase in the R*A product compared to comparable conventional power transistor that does not have the split gate configuration.

The split gate power transistor also improves the hot carrier lifetime compared to the comparable conventional power transistor of FIG. 2. This is due to the higher R*A product, which results in lower current densities. Further, the breakdown voltage BVdss is increased due to the constant voltage applied to the static gate. The portion of the static gate extending over the trench functions as a field plate. In general, a field plate reduces the electric field for any given supply voltage, which effectively maintains or increases the breakdown voltage of the split gate power transistor. In the split gate configuration, the breakdown voltage BVdss increases by the same amount of voltage as the constant voltage applied to the static gate. The improved hot carrier lifetime and increased breakdown voltage leads to partial recovery of the increase in the R*A product.

The following highlight some of the properties of the split gate power transistor of the second and third embodiments, especially as compared to a comparable power transistor. First, the gate capacitance and the gate charge are reduced because the switching portion of the gate, the switching gate, has a smaller gate area. Second, because a constant voltage is applied to the static gate that is over the transition region, the gate-to-drain feedback capacitance is greatly reduced. This further reduces the gate charge compared to a comparable power transistor because during switching, the gate-to-drain capacitance is amplified by the Miller effect. Third, the hot carrier lifetime is improved. Fourth, the breakdown voltage BVdss is increased. Fifth, switch mode power supply (SMPS) efficiency is improved. Sixth, the process of fabricating the split gate power transistor is CMOS compatible. As such, the split gate power transistor can be fabricated monolithically with CMOS devices, including the output circuits of a SMPS. Fabrication of a power MOSFET on the same integrated circuit as the SMPS circuit results in smaller overall SMPS system size and cost.

The operation of the split gate power transistor is described above as applying a switching voltage to the gate 130 and a static voltage to the gate 132. Alternatively, the split gate power transistor can be operated such that a constant voltage is applied to the gate 130 and a switching voltage is applied to the gate 132. In an example application, this alternatively configured power transistor functions as an integrated high voltage NAND gate. This integrated device reduces total device area compared to a conventional low-side switching device that connects a discrete CMOS device to a lateral DMOS.

The split gate power transistors 100 and 200 are shown and described above as having the same gate oxide thickness below both the static gate and the switching gate. In alternative embodiments, a stepped gate oxide can be used in a similar manner as that described above in relation to the lower-voltage split gate power transistor 400. Additionally, the split gate power transistors 100 and 200 can be adapted similarly as the split gate power transistor to use a lower voltage rated transistor for the switching gate and a higher voltage rated transistor for the static gate. In other words, the split gate power transistor 400 can be adapted for higher voltage applications within a DMOSFET configuration.

In an example application, the cut gap between the switching gate and the static gate is fabricated using 0.18 micron semiconductor processing technology, resulting in a 0.25 micron wide gap. However, the gap can be larger or smaller than 0.25 microns, limited in size only by the available technology. For example, utilization of 0.13 micron semiconductor fabrication technology can achieve a gap width of 0.2 microns. In practice, the gap can be as small as technology allows, thereby minimizing the overall size of the transistor, such as the half-pitch. In the example application using 0.18 semiconductor fabrication technology, the channel region is lengthened by 0.25 microns.

In general, the switching gate and the static gate can be depletion-mode MOS devices or enhancement-mode MOS devices. The bridge is required for the device to operate properly if the static gate is operated in enhancement mode.

Embodiments of the split gate power transistor are described above as N-channel MOSFETs. Alternative embodiments are also contemplated, for example a P-channel MOSFET. Application to a P-channel MOSFET requires a slightly different configuration. Alternative configurations can be implemented where the split gate power transistor is configured with all aspects having opposite polarities than those shown in the described embodiments.

The gate material is described above as being polysilicon. Alternatively, the gate can be made of any conventional material used in the fabrication of semiconductor transistors including, but not limited to, polysilicon and/or metal. The substrate is described above as being silicon. Alternatively, the substrate can be a silicon-based compound, for example silicon germanium (SiGe).

The split gate power transistor has been described in terms of specific embodiments incorporating details to facilitate the understanding of the principles of construction and operation of the power transistor. Such references, herein, to specific embodiments and details thereof are not intended to limit the scope of the claims appended hereto. It will be apparent to those skilled in the art that modifications can be made in the embodiments chosen for illustration without departing from the spirit and scope of the power transistor.

1. A power transistor comprising:
a. a doped substrate comprising a source, a first channel region, a bridge, a second channel region, and a drain, wherein the first channel region is positioned between the source and the bridge, and the second channel region is positioned between the bridge and the drain;
b. a first gate oxide layer positioned on the substrate over at least the first channel region;
c. a second gate oxide layer positioned on the substrate over at least the second channel region, wherein a thickness of the first gate oxide layer is less than a thickness of the second gate oxide layer;
d. a first gate positioned on the first gate oxide layer and over the first channel region; and
e. a second gate positioned on the second gate oxide layer and over the second channel region, wherein the first gate is separated from the second gate such that at least a portion of the bridge is uncovered by both the first gate and the second gate.

2. The power transistor of claim 1 wherein the first gate is electrically coupled to a first voltage supply, and the second gate is electrically coupled to a second voltage supply.

3. The power transistor of claim 1 wherein the first gate and the second gate are electrically isolated from each other.

4. (canceled)

5. (canceled)

6. (canceled)

7. (canceled)

8. The power transistor of claim 1 wherein the source, the first gate, and the bridge form a first enhancement-mode transistor and the bridge, the second gate, and the drain form a second enhancement-mode transistor.

9. The power transistor of claim 1 wherein the first gate and the second gate comprise polysilicon.

10. The power transistor of claim 1 wherein the source and the bridge are N-type regions and the first channel and the second channel are P-type regions.

11. The power transistor of claim 1 wherein the source, the second channel, and the bridge are N-type regions and the first channel is a P-type region.

12. The power transistor of claim 1 wherein the substrate comprises a silicon substrate.

13. The power transistor of claim 1 where the source comprises a double-diffused region.

14. A power transistor comprising:
a. a doped substrate comprising a source, a bridge, a first channel region, and a second channel region within a first doped region, a drain and a transition region within a second doped region, and a trench within a second doped region, wherein the trench is formed in a first surface of the substrate and the trench is filled with field oxide, further wherein the first channel region is positioned between the source and the bridge, the second channel region is positioned between the bridge and the transition region, the transition region is positioned between the second channel region and the trench, and the trench is positioned between the transition region and the drain;
b. a first gate oxide layer positioned on the first surface of the substrate over at least the first channel region;
c. a second gate oxide layer positioned on the first surface of the substrate over at least the second channel region, wherein a thickness of the first gate oxide layer is less than a thickness of the second gate oxide layer;
d. a first gate positioned on the first gate oxide layer and over the first channel region; and
e. a second gate positioned on the second gate oxide layer and over the second channel region, the transition region, and a portion of the trench, wherein the first gate is separated from the second gate such that at least a portion of the bridge is uncovered by both the first gate and the second gate.

15. (canceled)

16. The power transistor of claim 14 wherein the first gate and the second gate are electrically isolated from each other.

17. The power transistor of claim 14 wherein a constant voltage is applied to the second gate and a switching voltage is applied to the first gate.

18. The power transistor of claim 17 wherein the constant voltage is a bias voltage level that is less than a breakdown voltage of the first gate oxide.

19. (canceled)

20. (canceled)

21. The power transistor of claim 14 wherein the first gate and the second gate comprise polysilicon.

22. The power transistor of claim 14 wherein the source and the bridge are N-type regions and the first channel and the second channel are P-type regions.

23. The power transistor of claim 14 wherein the source, the second channel, and the bridge are N-type regions and the first channel is a P-type region.

24. (canceled)

25. (canceled)

26. The power transistor of claim 14 wherein the first doped region is a P-type region and the second doped region is a N-type region.

27. (canceled)

28. The power transistor of claim 14 wherein the doped substrate further comprises a drift region within the second doped region, wherein the drift region is positioned under the trench.

29. (canceled)

30. (canceled)

31. (canceled)

32. (canceled)

33. (canceled)

34. (canceled)

35. (canceled)

36. (canceled)

37. (canceled)
